(19) United States
(12) Patent Application Publication
(10) Pub. No.: US 2007/0090860 A1
(43) Pub. Date: Apr. 26, 2007

(54) VOLTAGE BUFFER CIRCUIT

(76) Inventor: Cheng-Chung Hsu, Chang-Hua Hsien (TW)

Correspondence Address: NORTH AMERICA INTELLECTUAL PROPERTY CORPORATION, P.O. BOX 506, MERRIFIELD, VA, 22116, US

(21) Appl. No.: 11/538,810

(22) Filed: Oct. 5, 2006

(30) Foreign Application Priority Data
Oct. 25, 2005 (TW) 094137302

(51) Int. Cl. H03B 1/00

(52) U.S. Cl. 327/108

(57) ABSTRACT

A voltage buffer circuit is disclosed for receiving an input voltage and generating an output voltage. The voltage buffer circuit includes a voltage buffer stage and a voltage output stage. The voltage buffer stage buffers the input voltage and generates a first voltage. The voltage buffer stage includes a first circuit. The voltage output stage is coupled to the voltage buffer stage for receiving the first voltage and generating the output voltage. The circuit structure of the voltage output stage corresponds to the circuit structure of the first circuit.

### BACKGROUND OF THE INVENTION

1. Field of the Invention

The invention relates to buffer circuit, and more particularly, to voltage buffer circuit.

2. Description of the Prior Art

Reference voltage generators are a kind of circuit frequently utilized by many kinds of electronic devices. Generally speaking, a reference voltage generator generates stable voltage levels that are demanded by a data conversion circuit, such as a digital-to-analog converter (DAC) or an analog-to-digital converter (ADC).

FIG. 1 shows a conventional reference voltage generator. The reference voltage generator 100 shown in FIG. 1 includes an operational amplifier A3, a transistor M1, a resistor R1, a resistor R2, and a current source CS1. With these components, two primitive reference voltages Vtop and Vbottom are generated, where Vtop=Vcom+I1*R1 and Vbottom=Vcom−I1*R2. Normally, R1=R2. To enhance the output driving ability of the reference voltage generator 100, an operational amplifier A1 is used to be a first voltage buffer circuit for buffering the first primitive reference voltage Vtop to generate a first reference voltage VR+. Besides, an operational amplifier A2 is used to be a second voltage buffer circuit for buffering the second primitive reference voltage Vbottom to generate a second reference voltage VR−.

FIG. 2 shows a circuit structure of a voltage buffer circuit, such as the operational amplifier A1 or A2, of FIG. 1. The voltage buffer circuit 10 shown in FIG. 2 includes a transistor M2, a transistor M3, a current source CS2, and a current source CS3. The voltage buffer circuit 10 applies compensation capacitors to increase feedback stability. On the other hands, the driving ability of voltage buffer circuit 10 also needs to be well concerned while designing and implementing.

### SUMMARY OF THE INVENTION

It is an object of the present invention to provide a voltage buffer circuit for buffering a reference voltage.

The invention discloses a voltage buffer circuit for generating a first output voltage according to a first input voltage. The voltage buffer circuit comprises: a first voltage buffer stage, for buffering the first input voltage and generating a first voltage, the first voltage buffer stage comprising a first circuit; and a first voltage output stage, coupled to the first voltage buffer stage, for receiving the first voltage and generating the first output voltage. Wherein the circuit structure of the first voltage output stage corresponds to the circuit structure of the first circuit.

The invention also discloses a voltage buffer circuit for generating an output voltage according to an input voltage. The voltage buffer circuit comprises: an operational amplifier having a first end coupled to the input voltage; a first current source, for providing a first bias current; a first transistor, having a control end coupled to an output end of the operational amplifier, and a first end coupled to a second input end of the operational amplifier and the first current source; a second current source, for providing a second bias current; and a second transistor, having a control end coupled to the output end of the operational amplifier, and a first end coupled to the second current source for generating the output voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a conventional reference voltage generator.

FIG. 2 shows a conventional voltage buffer circuit.

FIG. 3 and FIG. 4 show reference voltage generators having exemplary voltage buffer circuits of the present invention included therein.

FIG. 5 shows an exemplary voltage buffer circuit of the present invention.

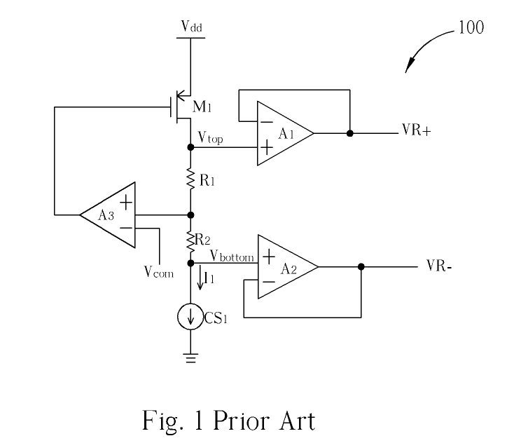

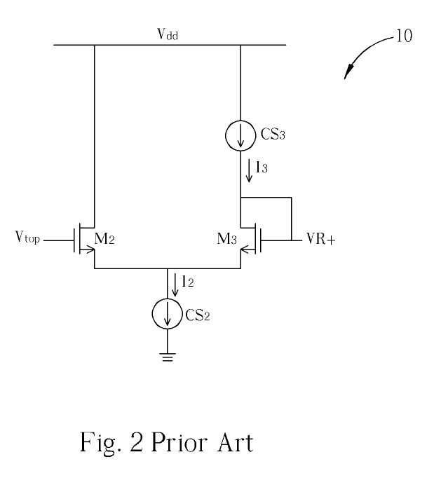

### DETAILED DESCRIPTION

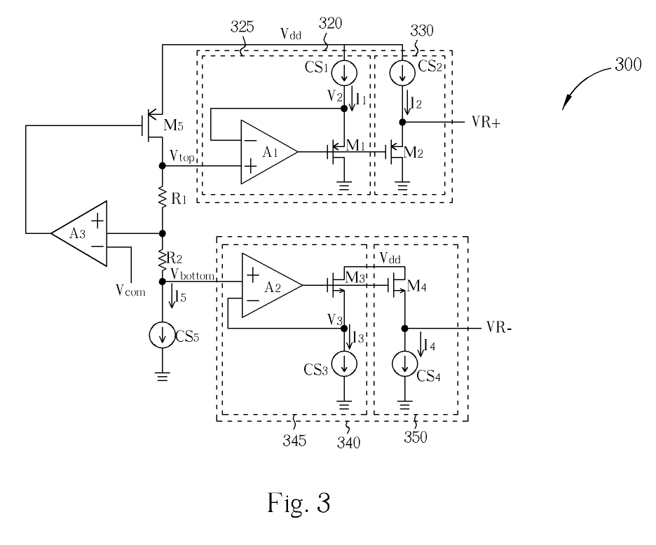

FIG. 3 shows a reference voltage generator having exemplary voltage buffer circuits of the present invention included therein. The reference voltage generator 300 of this embodiment includes a first voltage buffer circuit 320 and a second voltage buffer circuit 340. The first voltage buffer circuit 320 generates an output reference voltage VR+ according to a primitive reference voltage Vtop. The second voltage buffer circuit 340 generates an output reference voltage VR− according to a primitive reference voltage Vbottom. In an embodiment, the first and second voltage buffer circuits 320 and 340 have similar circuit structures.

The first voltage buffer circuit 320 comprises a buffer stage 325 and an output stage 330. The buffer stage 325, which comprises a first operational amplifier A1, a first current source CS1, and a first transistor M1, generates a voltage V2 according to the reference voltage Vtop. In the buffer stage 325, the first current source CS1 and the first transistor M1 constitutes a first circuit. A first input end of the first operational amplifier A1 is coupled to the reference voltage Vtop. An output end of the first operational amplifier A1 is coupled to a control end of the first transistor M1. The output stage 330, which comprises a second current source CS2 and a second transistor M2, is for generating the output reference voltage VR+. A control end of the second transistor M2 is interconnected with the control end of the first transistor M1 and the output end of operational amplifier A1. Since the structure of the output stage 330 is similar to that of the buffer stage 325, the output reference voltage VR+ will be substantially equal to the voltage V2. To ensure that the output reference voltage VR+ is substantially equal to the voltage V2, the voltage buffer circuit 320 will let the following equation to be satisfied:
I1/I2=(W1/L1)/(W2/L2)

where I1 and I2 are bias currents generated by the first and second current sources CS1 and CS2 respectively, and W1/L1 and W2/L2 are the aspect ratios of first and second transistors M1 and M2 respectively. On the other hands, the output reference voltage VR+ could also be designed not equal to the voltage V2 by adjusting the bias current I1, I2, aspect ratio (W1/L1) or aspect ratio (W2/L2) in accordance with the application of the voltage buffer circuit.

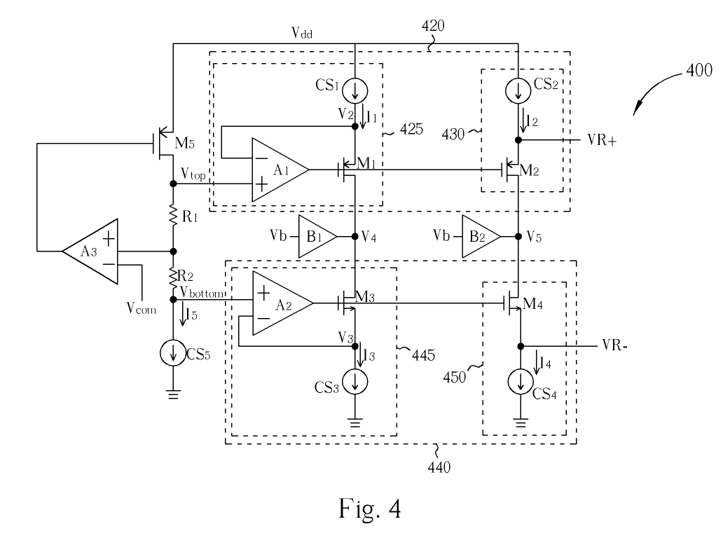

In one example, the bias current I1 that passes through the first transistor M1 is substantially equal to the bias current I3 that passes through the third transistor M3; and the bias current I2 that passes through the second current source CS2 and the second transistor M2 is substantially equal to the bias current I4 that passes through the fourth transistor M4. Under such circumstances, the bias currents shown in FIG. 3 can be shared. FIG. 4 shows a voltage buffer circuit 400 that is a modified version of the voltage buffer circuit 300 shown in FIG. 3. In the voltage buffer circuit 400, the first bias current I1 is substantially equal to the third bias current I3, and the drain of the first transistor M1 is coupled to the drain of the third transistor M3. Equivalently, the first current source CS1, the first transistor M1, the third transistor M3, and the third current source CS3 share a single bias current I1 that is also labeled as I3. Besides, the second bias current I2 is substantially equal to the fourth bias current 14, and the drain of the second transistor M2 is coupled to the drain of the fourth transistor M4. Equivalently, the second current source CS2, the second transistor M2, the fourth transistor M4, and the fourth current source CS4 share a single bias current I2 that is also labeled as I4.

The embodiment shown in FIG. 4 allows the following equations to be satisfied:
I1/I2=(W1/L1)/(W2/L2)
I3/I4=(W3/L3)/(W4/L4)

where I1, I2, I3, and I4 are bias currents provided by the first, second, third, and fourth current sources CS1, CS2, CS3, and CS4 respectively; W1/L1, W2/L2, W3/L3, and W4/L4 are aspect ratios of the first, second, third, and fourth transistors M1, M2, M3, and M4 respectively. On condition that the aforementioned equations are satisfied, the output reference voltage VR+ will be substantially equal to the voltage V2, and the output reference voltage VR− will be substantially equal to the voltage V3. Besides, to stabilize the voltage levels V4 and V5, the embodiment shown in FIG. 4 further comprises two buffers B1 and B2. The geometric ratio between the buffers B1 and B2 is substantially equal to the ratio between the currents I1 and I2 or the ratio between the currents I3 and I4.

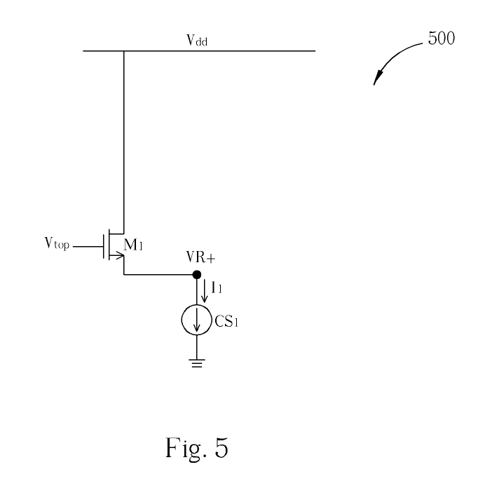

FIG. 5 shows a diagram of exemplary voltage buffer circuit of the present invention. The voltage buffer circuit 500 of this embodiment has circuit structure similar to that of the voltage output stage 330 shown in FIG. 3. In short, the voltage buffer circuit 500 generates an output voltage VR+, which can be provided to a data conversion circuit, according to an input voltage Vtop. The relationship between the output voltage VR+ and the input voltage Vtop is as follows:
VR+=Vtop−Vgs

where Vgs is the voltage difference between the gate and source of the transistor M1. The output voltage VR+ generated by the voltage buffer circuit 500 is slightly different from the input voltage Vtop.

According to the exemplary embodiment of the present invention, although the voltage buffer in disclosure is applied in a reference voltage generator, but not limited. It could also be applied in other application, such as amplifier, filter, driver . . . etc. On the other hands, according to the exemplary embodiment of the present invention, the output voltage VR+ or VR− of the voltage buffer can be used in many applications, such as data conversion circuit, pipeline ADC, flash ADC or any other circuits comprising reference voltage.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A voltage buffer circuit for generating a first output voltage according to a first input voltage, the voltage buffer circuit comprising:
a first voltage buffer stage, for buffering the first input voltage and generating a first voltage, the first voltage buffer stage comprising a first circuit; and
a first voltage output stage, coupled to the first voltage buffer stage, for receiving the first voltage and generating the first output voltage;
wherein the circuit structure of the first voltage output stage corresponds to the circuit structure of the first circuit.

2. The voltage buffer circuit of claim 1, wherein the first voltage buffer stage comprises:
a first operational amplifier having a first input end coupled to the first input voltage and an output end for generating the first voltage;
a first current source, for providing a first bias current; and
a first transistor having a first end coupled to a second input end of the first operational amplifier and the first current source, and a control end coupled to the output end of the first operational amplifier for receiving the first voltage;
wherein the first circuit comprises the first current source and the first transistor.

3. The voltage buffer circuit of claim 2, wherein the first voltage output stage comprises:
a second current source for providing a second bias current; and
a second transistor having a control end coupled to the output end of the first operational amplifier for receiving the first voltage, and a first end coupled to the second current source to form a first node for generating the first output voltage.

4. The voltage buffer circuit of claim 3, wherein the ratio between the first and second bias currents is substantially equal to the ratio between the aspect ratios of the first and second transistors.

5. The voltage buffer circuit of claim 1, wherein the voltage buffer circuit further generates a second output voltage according to a second input voltage, the voltage buffer circuit further comprises:
a second voltage buffer stage, for buffering the second input voltage and generating a second voltage, the second voltage buffer stage comprising a second circuit; and
a second voltage output stage, coupled to the second voltage buffer stage, for receiving the second voltage and generating the second output voltage;
wherein the circuit structure of the second voltage output stage corresponds to the circuit structure of the second circuit.

6. The voltage buffer circuit of claim 5, wherein the second voltage buffer stage comprises:
a second operational amplifier having a first input end coupled to the second input voltage and an output end for generating the second voltage;
a third current source, for providing a third bias current; and
a third transistor having a first end coupled to a second input end of the second operational amplifier and the third current source, and a control end coupled to the output end of the second operational amplifier for receiving the second voltage;
wherein the second circuit comprises the third current source and the third transistor.

7. The voltage buffer circuit of claim 6, wherein the second voltage output stage comprises:
a fourth current source, for providing a fourth bias current; and
a fourth transistor having a control end coupled to the output end of the second operational amplifier for receiving the second voltage, and a first end coupled to the fourth current source to form a second node for generating the second output voltage.

8. The voltage buffer circuit of claim 7, wherein the ratio between the third and fourth bias currents is substantially equal to the ratio between the aspect ratios of the third and fourth transistors.

9. The voltage buffer circuit of claim 5, wherein the first and second circuits share a first bias current, and the first and second voltage output stages share a second bias current.

10. The voltage buffer circuit of claim 9, further comprising:
a first buffer, for providing a joint voltage to the first and second voltage buffer stages; and
a second buffer, for providing the joint voltage to the first and second voltage output stages.

11. The voltage buffer circuit of claim 10, wherein the geometric ratio between the first and second buffers is substantially equal to the ratio between the first and second bias currents.

12. A voltage buffer circuit for generating an output voltage according to an input voltage, the voltage buffer circuit comprising:
an operational amplifier having a first input end, a second input end and an output end; wherein the first input end couples to the input voltage;
a first current source for providing a first bias current;
a first transistor having a control end coupled to the output end of the operational amplifier, and a first end coupled to the second input end of the operational amplifier and the first current source;
a second current source for providing a second bias current; and
a second transistor having a control end coupled to the output end of the operational amplifier, and a first end coupled to the second current source for outputting the output voltage.

13. The voltage buffer circuit of claim 12, wherein the ratio between the aspect ratios of the first and second transistors corresponds to the ratio between the first and second currents.

14. The voltage buffer circuit of claim 13, wherein the second transistor corresponds to the first transistor, and the second current source corresponds to the first current source.

15. The voltage buffer circuit of claim 13, wherein the voltage buffer circuit outputs the output voltage to a data conversion circuit.

16. A voltage buffer circuit for generating an output voltage according to an input voltage, the voltage buffer circuit comprising:
an operational amplifier having a first input end, a second input end and an output end, wherein the first input end couples to the input voltage;
a first current source for providing a first bias current;
a first transistor having a control end coupled to the output end of the operational amplifier, and a first end coupled to the second input end of the operational and the first current source; and
an output stage coupled to the operational amplifier for outputting the output voltage.

17. The voltage buffer circuit of claim 16, wherein the output stage comprises:
a second current source for providing a second bias current; and
a second transistor having a control end coupled to the output end of the operational amplifier, and a first end coupled to the second current source for outputting the output voltage.

18. The voltage buffer circuit of claim 16, wherein the output voltage is corresponding to the first bias current.

19. The voltage buffer circuit of claim 16, wherein the output voltage is corresponding to the aspect ratio of the first transistor.

20. The voltage buffer circuit of claim 16, wherein the voltage buffer circuit outputs the output voltage to a data conversion circuit.
